(19) United States
(12) Patent Application Publication
(10) Pub. No.: US 2025/0266301 A1
(43) Pub. Date: Aug. 21, 2025

(54) SEMICONDUCTOR MANUFACTURING DEVICE AND METHOD OF MANUFACTURING SEMICONDUCTOR DEVICE

(71) Applicant: Mitsubishi Electric Corporation, Tokyo (JP)

(72) Inventor: Hideta KUMAMOTO, Kumamoto (JP)

(73) Assignee: Mitsubishi Electric Corporation, Tokyo (JP)

(21) Appl. No.: 18/974,664

(22) Filed: Dec. 9, 2024

(30) Foreign Application Priority Data
Feb. 19, 2024 (JP) 2024-023055

(51) Int. Cl. H01L 21/66; G01R 1/067; H01L 21/683

(52) U.S. Cl. CPC H01L 22/14; G01R 1/06733; H01L 21/6836; H01L 2221/68327

(57) ABSTRACT

Provided are a semiconductor manufacturing device capable of performing an electrical characteristic inspection while a divided chip is attached to a dicing tape and a method of manufacturing a semiconductor device. A semiconductor device include: a stage on which a dicing tape to which a plurality of semiconductor chips are attached is disposed; a probe pin provided to the stage and inserted into an inner part of the dicing tape to be electrically connected to the semiconductor chips; and a tester performing an electrical characteristic inspection on the semiconductor chips via the probe pin.

### BACKGROUND OF THE INVENTION

### Field of the Invention

The present disclosure relates to a semiconductor manufacturing device and a method of manufacturing a semiconductor device.

### Description of the Background Art

A semiconductor device in a wafer state or a chip state has been conventionally measured to perform an electrical characteristic inspection on a semiconductor device having a front surface and a back surface both serving as an electrode. However, damage in a dicing process of dividing a chip cannot be considered in the measurement in the wafer state, and a divided chip needs to be transferred in the measurement in the chip state, so that there is a problem of a defect regarding the transportation and increase of cost in a facility investment. Thus, proposed in Japanese Patent Application Laid-Open No. 2014-229635 is a technique of using a dicing tape with a plurality of holes formed to fit a position of a divided chip in a wafer and measuring the divided chip on the dicing tape.

### SUMMARY

However, since dicing is performed using the dicing tape having the holes in Patent Document 1, there is concern that fixing force of the wafer is weakened in dicing. An object of the present disclosure is to provide a semiconductor manufacturing device capable of performing an electrical characteristic inspection while a divided chip is attached to a dicing tape and a method of manufacturing a semiconductor device.

A semiconductor manufacturing device according to the present disclosure includes a stage, a probe pin, and a tester. A dicing tape to which a plurality of semiconductor chips are attached is disposed on the stage. The probe pin is provided to the stage, and is inserted into an inner part of the dicing tape to have contact with the semiconductor chips. The tester performs an electrical characteristic inspection on the semiconductor chips via the probe pin.

According to the semiconductor manufacturing device of the present disclosure, the electrical characteristic inspection can be performed on the divided chip attached to the dicing tape.

A method of manufacturing a semiconductor device according to the present disclosure includes an insertion process and an inspection process. In the insertion process, a probe pin provided to a stage is inserted into an inner part of a dicing tape while the dicing tape to which a plurality of semiconductor chips are attached is disposed on the stage, and is electrically connected to the semiconductor chips. In the inspection process, an electrical characteristic inspection is performed on the semiconductor chips via the probe pin.

According to the method of manufacturing the semiconductor device according to the present disclosure, the electrical characteristic inspection can be performed on the divided chip attached to the dicing tape.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating a semiconductor manufacturing device according to an embodiment 1.

FIG. 2 is a cross-sectional view illustrating the semiconductor manufacturing device according to the embodiment 1.

FIG. 3 is a flow chart diagram of a method of manufacturing a semiconductor device using the semiconductor manufacturing device according to the embodiment 1.

FIG. 4 is a cross-sectional view illustrating a semiconductor manufacturing device according to an embodiment 2.

FIG. 5 is a cross-sectional view illustrating a semiconductor manufacturing device according to an embodiment 3.

FIG. 6 is a cross-sectional view illustrating the semiconductor manufacturing device according to the embodiment 3.

FIGS. 7A and 7B are diagrams illustrating a method of manufacturing a semiconductor device using a modification example of the semiconductor manufacturing device according to the embodiment 3.

FIG. 8 is a flow chart diagram illustrating a method of manufacturing a semiconductor device using a semiconductor manufacturing device according to a comparative example.

FIG. 9 is a diagram illustrating a modification example of a dicing tape.

### DESCRIPTION OF THE PREFERRED EMBODIMENTS

An embodiment is described hereinafter with reference to the diagrams. Since the diagrams are schematically illustrated, a mutual relationship of a size and a position can be changed. In the description hereinafter, the same reference numerals are assigned to the same or corresponding constituent elements, and the repetitive description is omitted in some cases.

Used in the description hereinafter are terms each indicating a specific position and direction such as “upper”, “lower”, and “side”, for example; however, these terms are used for convenience of easy understanding of contents of the embodiments, and do not limit a position and a direction in implementation.

### Embodiment 1

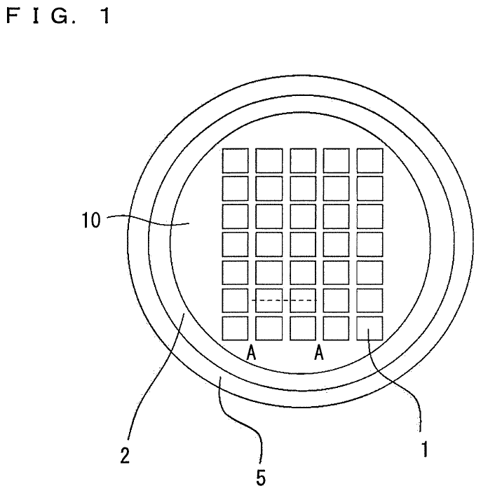

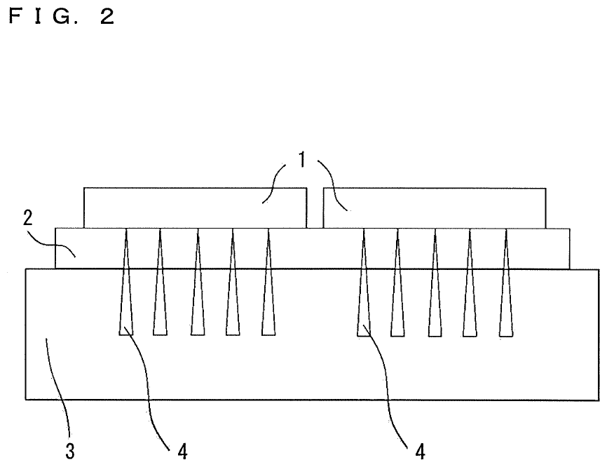

FIG. 1 and FIG. 2 illustrate a semiconductor manufacturing device according to an embodiment 1. FIG. 1 is a plan view illustrating the semiconductor manufacturing device according to the embodiment 1, and is a plan view illustrating a semiconductor wafer 10 held by a mount frame 5. FIG. 2 is a cross-sectional view illustrating the semiconductor manufacturing device according to the embodiment 1, and is a cross-sectional view along a broken line A-A in FIG. 1 in a state where the semiconductor wafer 10 is disposed on a stage 3.

The semiconductor wafer 10 includes an electrode (not shown) not only on a front surface but also on a back surface, and a dicing tape 2 is attached to the semiconductor wafer 10 via the electrode. A material of the electrode is metal such as gold or aluminum, for example. A semiconductor material made of Si or SiC, GaN, or Ga2O3 as wide bandgap semiconductor, for example, may be used for the semiconductor wafer 10. A diode or an insulated gate bipolar transistor (IGBT) or a metal oxide semiconductor field effect transistor (MOSFET) as a switching element, for example, is formed as a semiconductor element in the semiconductor wafer 10.

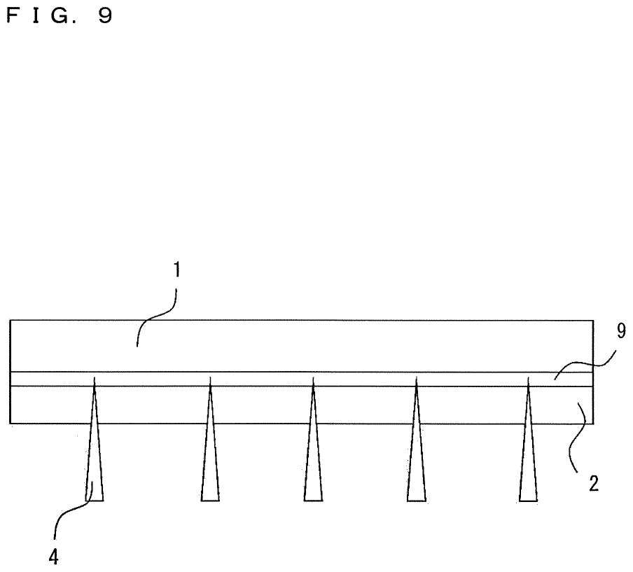

FIGS. 1 and 2 illustrate a state where the semiconductor wafer 10 has been diced. The semiconductor wafer 10 is diced to be a plurality of divided semiconductor chips 1, and each chip is arranged on the dicing tape 2 at regular intervals. The dicing tape 2 is an adhesive tape in which an adhesive material is provided to a side attached to the semiconductor wafer 10. Any material is applicable to the adhesive material as long as it has ultraviolet response properties and has decreasing adhesive force in response to ultraviolet compared with a state before being irradiated with the ultraviolet, for example, and UV-curable polyolefin is applicable, for example. The dicing tape 2 does not include a hole. Herein, FIG. 9 illustrates a modification example of the dicing tape 2. As illustrated in FIG. 9, a conductive adhesive material 9 having conductivity may be used as the adhesive material of the dicing tape 2.

It is applicable that a plurality of absorption hole (not shown) are formed in the stage 3, the absorption holes are provided in positions different from the probe pin 4, and the semiconductor chip 1 is absorbed to the stage 3 by an absorption action from the absorption holes via the dicing tape 2. The plurality of absorption holes are preferably disposed to be symmetric with respect to a center of the wafer.

The probe pin 4 is electrically connected to a tester (not shown) to serve as a probe terminal for performing electrical characteristic inspection. The probe pin 4 has a decreasing diameter toward a tip end, thus can be inserted into an inner part of the dicing tape 2 to achieve electrical connection to a back surface of the semiconductor chip 1.

It is sufficient that the probe pin 4 is made of a material capable of passing through the dicing tape 2. However, the same material as that of the back surface of the semiconductor wafer 10 or a more flexible material capable of passing through the dicing tape 2 is preferable, and is metal capable of suppressing damage on the back surface of the semiconductor chip 1, for example.

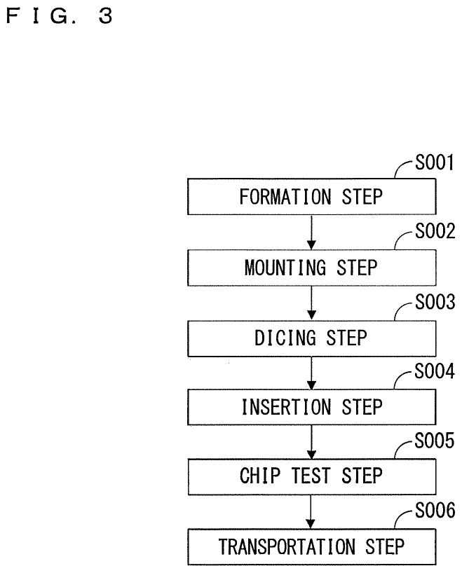

Described herein is a method of manufacturing a semiconductor device using the semiconductor manufacturing device according to the embodiment 1. FIG. 3 is a flow chart diagram of the method of manufacturing the semiconductor device using the semiconductor manufacturing device according to the embodiment 1.

In a formation process S001 of manufacturing the semiconductor wafer 10, ion implantation, for example, is performed to form a plurality of semiconductor elements in a matrix form in the semiconductor wafer 10.

Subsequently, in a mounting process S002, the semiconductor wafer 10 as a processed object is attached to a center of the dicing tape 2 held by the ring-like mount frame 5. The mount frame 5 is an annular frame, and it is applicable that the mount frame 5 is made of metal as a material and processing of forming a passive film is performed on a surface, or is made of a resin material.

The dicing tape 2 is an adhesive tape in which an adhesive material is provided to a side attached to the semiconductor wafer 10. The adhesive material is a material with ultraviolet response properties so as to have decreasing adhesive force in response to ultraviolet compared with a state before being irradiated with the ultraviolet, for example. The dicing tape 2 does not include a hole.

It is also applicable to perform a protection tape attachment process (not shown) before the mounting process S002 and attach a protection tape (not shown) as a tape for protecting a pattern of forming the semiconductor element provided to the front surface of the semiconductor wafer 10. The pattern of forming the semiconductor element is thereby protected in subsequent processes. In a dicing process S003, since the semiconductor wafer 10 is cut while the protection tape is kept attached, a breakage or a crack of the semiconductor wafer 10 can be suppressed in the cutting process. The protection tape is detached at least before a chip test process S005.

The adhesive material of the protection tape is a material having ultraviolet response properties and having decreasing adhesive force in response to ultraviolet compared with a state before being irradiated with the ultraviolet, for example.

Subsequently, in the dicing process S003, the semiconductor wafer 10 attached to the dicing tape 2 is divided to be in a chip state from a wafer state, and the plurality of semiconductor chips 1 are formed in a lattice form. In dividing the semiconductor wafer 10, only the semiconductor wafer 10 is cut and diced, and the dicing tape 2 is not cut. The dicing is performed by blade dicing or laser dicing, for example.

Subsequently, in an insertion process S004, the probe pin 4 is inserted into the inner part of the dicing tape 2 while the semiconductor chip 1 is disposed on the dicing tape 2 to be electrically connected to the divided semiconductor chip 1. The probe pin 4 has a decreasing diameter toward a tip end, thus can be inserted into the inner part of the dicing tape 2 to achieve electrical connection to the back surface of the semiconductor chip 1. When the probe pin 4 is provided to an inner part of the stage 3 and protrudes to an upper side from the surface of the stage 3, the probe pin 4 passes through the dicing tape 2 to have contact with the semiconductor chip 1.

Since the probe pin 4 passes through the dicing tape 2 while the semiconductor chip 1 and the dicing tape 2 are absorbed to the stage 3, the probe pin 4 can have contact with the semiconductor chip 1 with high accuracy. It is applicable only one probe pin 4 passes through the dicing tape 2 to have contact with one semiconductor chip1 or the plurality of probe pins 4 have contact with one semiconductor chip 1. That is to say, the number of pins passing through the dicing tape 2 may be optionally changed in accordance with a size of the semiconductor chip 1.

As illustrated in FIG. 9, when the conductive adhesive material 9 is provided to a surface of the dicing tape 2, the probe pin 4 needs not pass through the dicing tape 2. When the conductive adhesive material 9 is provided, conduction can be achieved before the probe pin 4 has contact with the back surface of the semiconductor chip 1. That is to say, when the tip end of the probe pin 4 reaches the conductive adhesive material 9, the probe pin 4 needs not have contact with the back surface of the semiconductor chip 1; thus, damage on the semiconductor chip 1 by pressing force of the probe pin 4 can be prevented, and productivity is also improved.

Subsequently, in a chip test process S005, an electrical signal is applied to the semiconductor chip 1 from the probe pin 4 while the dicing tape 2 is attached, and electrical characteristic inspection and an appearance inspection, for example, is performed on the semiconductor chip 1.

Subsequently, in a transportation process S006, the divided chip is picked up from the dicing tape and is transported. In picking up the semiconductor chip 1 after the probe pin 4 passes through the dicing tape 2 and the chip test is performed, it is also applicable to pick up the semiconductor chip 1 by further holding up the probe pin 4 electrically connected to the semiconductor chip 1. When the probe pin 4 is held up to pick up the semiconductor chip 1 after the chip test, productivity is improved. In consideration of picking up the semiconductor chip 1, the plurality of probe pins 4 passing through the dicing tape 2 are preferably disposed on a side of a center of the chip or disposed to be symmetric with respect to the center of the wafer in one semiconductor chip 1.

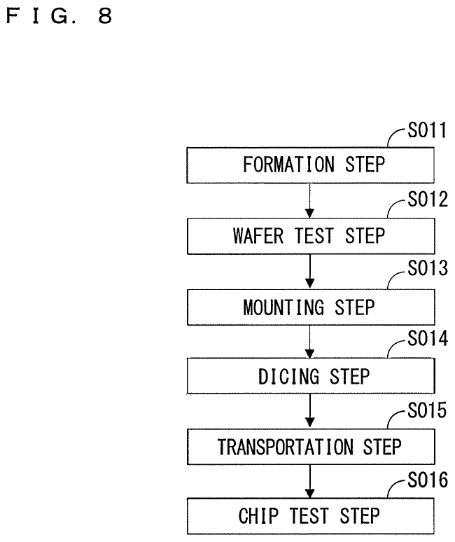

In the meanwhile, FIG. 8 is a flow chart diagram illustrating a method of manufacturing a semiconductor device using a semiconductor manufacturing device according to a comparative example.

The semiconductor manufacturing device according to the comparative example is different from the semiconductor manufacturing device according to the embodiment 1 in that a probe pin does not pass through the dicing tape. That is to say, in the semiconductor manufacturing device according to the comparative example, the prove pin is used only for picking up the semiconductor chip from the dicing tape, thus does not have a decreasing diameter toward the tip end so as to be able to pass through the diving tape.

In a formation process S011 of manufacturing the semiconductor wafer, ion implantation, for example, is performed to form a plurality of semiconductor elements in a matrix form in the semiconductor wafer. In a wafer test process S012, an electrical characteristic inspection or an appearance inspection, for example, is performed on the semiconductor wafer in a wafer state.

In a mounting process S013, the semiconductor wafer as a processed object is attached to a center of a dicing tape held by a ring-like mount frame. Subsequently, in the dicing process S014, the semiconductor wafer attached to the dicing tape is divided to be in a chip state from a wafer state. In dividing the semiconductor wafer, only the wafer is cut and diced, and the dicing tape is not cut.

Subsequently, in a transportation process S015, the divided chip is picked up from the dicing tape and is transported. Subsequently, in a chip test process S016, an electrical characteristic inspection or an appearance inspection, for example, is performed on the semiconductor wafer in a chip state.

In the comparative example, the electrical characteristic inspection is performed on the semiconductor wafer in the wafer state before the mounting process S013, and the electrical characteristic inspection is performed on the divided semiconductor wafer in the chip state after the transportation process S015. Damage in the dicing process S014 of dividing the chip cannot be considered only by the measurement of the semiconductor chip in the wafer state, and semiconductor chip in the chip state also needs to be measured; thus, the electrical characteristic inspection is performed twice, and the number of processes increases. In the measurement of the semiconductor chip in the chip state, the divided chip is picked up, and then needs to be transported by a chip tray, for example, and inspected; thus, defect regarding the transportation is concerned as a problem.

In the method of manufacturing the semiconductor device using the semiconductor manufacturing device according to the embodiment 1, since the probe pin 4 having a decreasing diameter toward the tip end is used as the measurement terminal after the dicing process S003, the probe pin 4 is inserted into the inner part of the dicing tape 2 to be electrically connected to the divided semiconductor chip 1. Accordingly, the electrical characteristic inspection can be performed on the semiconductor chip 1 while the dicing tape 2 is attached, and detection and determination of a non-defective product and a defective product can be performed. That is to say, the above problem can be solved, the electrical characteristic inspection can be performed with one inspection operation in consideration of the damage in the dicing process S003 without defect regarding the transportation, and productivity is improved. Compared with the conventional technique of making the probe pin have contact with the semiconductor chip in a part of the hole using the dicing tape having the holes, the dicing tape with no hole is used for the dicing tape 2 in the semiconductor manufacturing device according to the embodiment 1; thus, there is no concern that fixing force of the semiconductor wafer 10 decreases in dicing.

### Embodiment 2

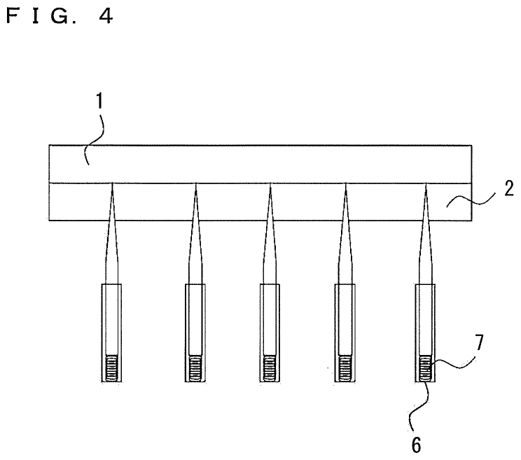

A configuration of a semiconductor manufacturing device according to an embodiment 2 is described using FIG. 4. FIG. 4 is a cross-sectional view illustrating the semiconductor manufacturing device according to the embodiment 2. In the embodiment 2, the same reference numerals are assigned to the same constituent elements as those described in the embodiment 1, and the same applies to each embodiment described hereinafter.

The semiconductor manufacturing device according to the embodiment 2 is different from the semiconductor manufacturing device according to the embodiment 1 in that a spring probe 6 is provided in place of the probe pin 4 as illustrated in FIG. 4. The spring probe 6 has a structure including a spring 7 as a spring and having a decreasing diameter toward a tip end, and pressing force of making the tip end of the spring probe 6 have contact with the semiconductor chip 1 can be made constant. The spring probe 6 has conductivity, and an electrical signal from the tip end of the spring probe 6 electrically connected to the semiconductor chip 1 is inputted to a tester (not shown) via the spring 7.

When the semiconductor device is manufactured using the semiconductor manufacturing device according to the embodiment 2, force of the probe pin 4 holding up the semiconductor chip 1 can be made constant by using the spring probe 6; thus, the probe pin 4 passes through the dicing tape 2, and the damage on the semiconductor chip 1 can be prevented. Since the electrical contact state between the semiconductor chip 1 and the spring probe 6 can be kept favorable, contact defect therebetween can be suppressed, and productivity can be improved.

### Embodiment 3

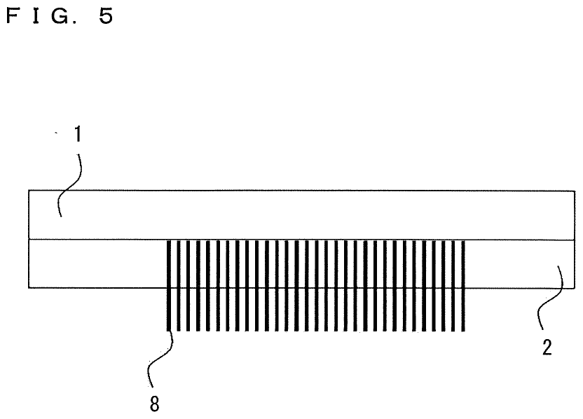

A configuration of a semiconductor manufacturing device according to an embodiment 3 is described using FIG. 5. FIG. 5 is a cross-sectional view illustrating the semiconductor manufacturing device according to the embodiment 3.

The semiconductor manufacturing device according to the embodiment 3 is different from the semiconductor manufacturing device according to the embodiment 1 and the semiconductor manufacturing device according to the embodiment 2 in that a wire probe 8 is provided in place of the probe pin 4 in the embodiment 1 and the spring probe 6 in the embodiment 2 as illustrated in FIG. 5. It is sufficient that the wire probe 8 is formed of conductor such as metal including tungsten, high-speed steel (SKH), or beryllium steel (Be—Cu), for example, and is formed into a wire-like shape having bendable elasticity. An outer peripheral surface of the wire probe 8 includes an insulating covering for covering the conductor described above. The insulating covering is formed of an insulator such as synthetic resin. The insulating covering may be an insulating covering formed by applying insulating coating to a surface of the conductor.

In the wire probe 8, one end has contact with the semiconductor chip 1 as an inspection target, and the other end is fixed by a support member (not shown). It is sufficient that the support member fixes the wire probe 8, and the support member may be made of an insulative material. The plurality of wire probes 8 are disposed at regular intervals on the support member. The interval of the plurality of wire probes 8 can be optionally changed in accordance with the size of the semiconductor chip 1.

The wire probe 8 is formed into a thin wire-like shape, thus can bow and absorb pressing force. Since the wire probe 8 is a thin wire-like prove, an arrangement pitch between the probes can be reduced. Thus, the wire probe 8 has a structure that the number of pins can be increased more easily than the probe pin 4 and the spring probe 6, and can deal with an inspection with larger current. It is sufficient that the wire probe 8 has a shape capable of passing through the dicing tape 2. However, a tip end thereof may have an R-like shape. When the tip end has the R-like shape, damage on the semiconductor chip 1 can be suppressed.

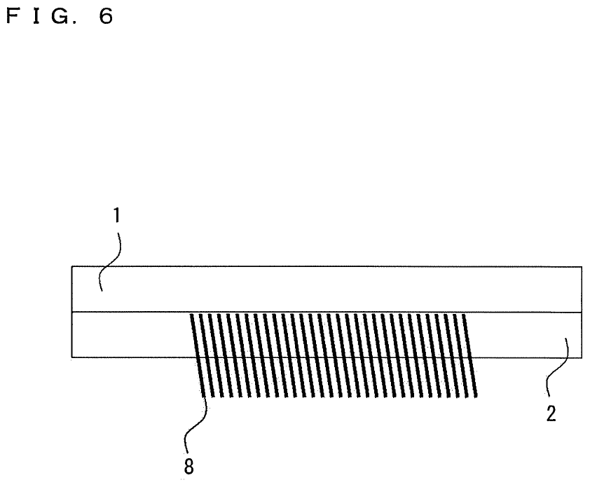

FIG. 6 is a cross-sectional view illustrating a modification example of the semiconductor manufacturing device according to the embodiment 3 and a modification example of the semiconductor manufacturing device illustrated in FIG. 5. Although the wire probe 8 has contact with the back surface of the semiconductor chip 1 from a vertical direction in the semiconductor manufacturing device according to the embodiment 3, the wire probe 8 may have contact with the back surface of the semiconductor chip 1 from an inclined direction in the modification example of the semiconductor manufacturing device according to the embodiment 3 as illustrated in FIG. 6. Since an insertion angle of the wire probe 8 inserted into the inner part of the dicing tape 2 is inclined with respect to the dicing tape 2, pressing force on the back surface of the chip in contact with the semiconductor chip 1 can be reduced, and damage on the semiconductor chip 1 can be suppressed.

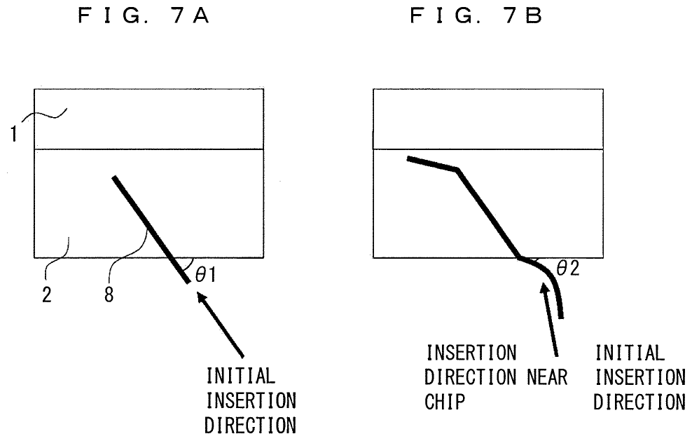

FIGS. 7A and 7B are diagrams illustrating a method of manufacturing a semiconductor device using a modification example of the semiconductor manufacturing device according to the embodiment 3. FIG. 7A illustrates an initial state where the wire probe 8 is inserted but has not had contact with the semiconductor chip 1 yet. FIG. 7B illustrates a state immediately before the wire probe 8 has contact with the chip.

As illustrated in FIGS. 7A and 7B, after the wire probe 8 is inserted, a part of the wire probe 8 which is not inserted into the dicing tape bows before the tip end of the wire probe 8 has contact with the semiconductor chip 1 to change the insertion angle of the wire probe 8 in a midway part of the inner part of the dicing tape 2. Since the insertion angle of the wire probe 8 may be changed in multiple levels, as illustrated in FIGS. 7A and 7B, the insertion of the wire probe 8 proceeds while a first insertion angle θ1 with respect to the dicing tape 2 is changed to a second insertion angle θ2 smaller than the first insertion angle immediately before the wire probe 8 has contact with the semiconductor chip 1. In the initial state where the wire probe 8 is firstly inserted into the dicing tape 2, the wire probe 8 is inserted more easily as the insertion direction thereof gets closer to a vertical direction with respect to an extension direction of the dicing tape. That is to say, the insertion is performed more easily as θ1 gets closer to 90°; however, in the meanwhile, stress on the back surface of the semiconductor chip 1 increases. Since the insertion of the wire probe 8 proceeds while the insertion angle of the wire probe 8 is changed to the second insertion angle θ2 smaller than the first insertion angle θ1 at the time of the initial insertion while the wire probe 8 is inserted into the midway part of the inner part of the dicing tape 2, the pressing force on the back surface of the semiconductor chip 1 can be reduced while the wire probe 8 can be inserted into the dicing tape 2 easily, and the damage on the semiconductor chip 1 can be suppressed. An angle adjustment means (not shown) may be provided to incline the insertion angle of the wire probe 8 into the dicing tape 2. When the angle adjustment means moves a support member supporting the wire probe 8, the insertion angle can be optionally changed. Any mechanism is applicable to the angle adjustment means as long as the insertion angle is optionally changed.

Although the embodiments of the present disclosure are described, these embodiments are proposed as the examples. The configuration can be variously omitted, replaced, or changed without departing from the scope of the present disclosure. Each embodiment can be combined.

The aspects of the present disclosure are collectively described hereinafter as appendixes.

### APPENDIX 1

A semiconductor manufacturing device, comprising:
a stage on which a dicing tape to which a plurality of semiconductor chips are attached is disposed;
a probe pin provided to the stage and inserted into an inner part of the dicing tape to be electrically connected to the semiconductor chips; and
a tester performing an electrical characteristic inspection on the semiconductor chips via the probe pin.

### APPENDIX 2

The semiconductor manufacturing device according to Appendix 1, wherein the prove pin is a wire probe.

### APPENDIX 3

The semiconductor manufacturing device according to Appendix 1, wherein the prove pin is a spring probe.

### APPENDIX 4

The semiconductor manufacturing device according to any of Appendixes 1 to 3, further comprising
an angle adjustment means of adjusting an insertion angle of the probe pin inserted into the inner part of the dicing tape.

### APPENDIX 5

A method of manufacturing a semiconductor device, comprising:
an insertion step of inserting a probe pin provided to a stage into an inner part of a dicing tape while the dicing tape to which a plurality of semiconductor chips are attached is disposed on the stage, and electrically connecting the probe pin to the semiconductor chips; and
an inspection step of performing an electrical characteristic inspection on the semiconductor chips via the probe pin.

### APPENDIX 6

The method of manufacturing the semiconductor device according to Appendix 5, wherein
in the insertion step, the probe pin is inserted into the dicing tape at a first angle between the dicing tape and the probe pin in a cross-sectional view.

### APPENDIX 7

The method of manufacturing the semiconductor device according to Appendix 6, wherein
in the insertion step, the probe pin bows after insertion of the probe pin at the first angle is started, and an angle between the dicing tape and the probe pin is changed to a second angle smaller than the first angle between the dicing tape and the probe pin in a cross-sectional view.

### APPENDIX 8

The method of manufacturing the semiconductor device according to any one of Appendixes 5 to 7, wherein
the dicing tape is a material cured by UV irradiation.

### APPENDIX 9

The method of manufacturing the semiconductor device according to any one of Appendixes 5 to 8, wherein
the dicing tape includes a conductive adhesive part, and the probe pin has contact with the adhesive part in the insertion step.

While the invention has been shown and described in detail, the foregoing description is in all aspects illustrative and not restrictive. It is therefore understood that numerous modifications and variations can be devised without departing from the scope of the invention.

What is claimed is:

1. A semiconductor manufacturing device, comprising:
a stage on which a dicing tape to which a plurality of semiconductor chips are attached is disposed;
a probe pin provided to the stage and inserted into an inner part of the dicing tape to be electrically connected to the semiconductor chips; and
a tester performing an electrical characteristic inspection on the semiconductor chips via the probe pin.

2. The semiconductor manufacturing device according to claim 1, wherein
the prove pin is a spring probe.

3. The semiconductor manufacturing device according to claim 1, wherein
the prove pin is a wire probe.

4. The semiconductor manufacturing device according to claim 1, further comprising
an angle adjustment means of adjusting an insertion angle of the probe pin inserted into the inner part of the dicing tape.

5. A method of manufacturing a semiconductor device, comprising:
an insertion step of inserting a probe pin provided to a stage into an inner part of a dicing tape while the dicing tape to which a plurality of semiconductor chips are attached is disposed on the stage, and electrically connecting the probe pin to the semiconductor chips; and
an inspection step of performing an electrical characteristic inspection on the semiconductor chips via the probe pin.

6. The method of manufacturing the semiconductor device according to claim 5, wherein
in the insertion step, the probe pin is inserted into the dicing tape at a first angle between the dicing tape and the probe pin in a cross-sectional view.

7. The method of manufacturing the semiconductor device according to claim 6, wherein
in the insertion step, the probe pin bows after insertion of the probe pin at the first angle is started, and an angle between the dicing tape and the probe pin is changed to a second angle smaller than the first angle between the dicing tape and the probe pin in a cross-sectional view.

8. The method of manufacturing the semiconductor device according to claim 7, wherein
the dicing tape is a material cured by UV irradiation.

9. The method of manufacturing the semiconductor device according to claim 5, wherein
the dicing tape includes a conductive adhesive part, and the probe pin has contact with the adhesive part in the insertion step.

10. The semiconductor manufacturing device according to claim 2, further comprising
an angle adjustment means of adjusting an insertion angle of the probe pin inserted into the inner part of the dicing tape.

11. The semiconductor manufacturing device according to claim 3, further comprising
an angle adjustment means of adjusting an insertion angle of the probe pin inserted into the inner part of the dicing tape.

12. The method of manufacturing the semiconductor device according to claim 5, wherein
the dicing tape is a material cured by UV irradiation.

13. The method of manufacturing the semiconductor device according to claim 6, wherein
the dicing tape is a material cured by UV irradiation.

14. The method of manufacturing the semiconductor device according to claim 6, wherein
the dicing tape includes a conductive adhesive part, and the probe pin has contact with the adhesive part in the insertion step.

15. The method of manufacturing the semiconductor device according to claim 7, wherein
the dicing tape includes a conductive adhesive part, and the probe pin has contact with the adhesive part in the insertion step.

16. The method of manufacturing the semiconductor device according to claim 8, wherein
the dicing tape includes a conductive adhesive part, and the probe pin has contact with the adhesive part in the insertion step.
